(19) United States
(12) Patent Application Publication
(10) Pub. No.: US 2018/0197931 A1
(43) Pub. Date: Jul. 12, 2018

(54) OLED DISPLAY PANEL AND OLED DISPLAY APPARATUS

(71) Applicant: Wuhan China Star Optoelectronics Technology Co., Ltd., Wuhan, Hubei (CN)

(72) Inventors: Bo LIANG, Shenzhen (CN); Jun LI, Shenzhen (CN); Wei WANG, Shenzhen (CN)

(73) Assignee: Wuhan China Star Optoelectronics Technology Co., L td., Wuhan, Hubei (CN)

(21) Appl. No.: 15/325,080

(22) PCT Filed: Jan. 7, 2017
(86) PCT No.: PCT/CN2017/070525

§ 371 Date: Jan. 9, 2017

(30) Foreign Application Priority Data
Dec. 15, 2016 (CN) 2016111599557

(51) Int. Cl. H01L 27/32; H01L 51/00; H01L 51/05; G09G 3/3233; H01L 51/52

(52) U.S. Cl. CPC H01L 27/3262; H01L 51/0097; H01L 51/5237; G09G 3/3233; H01L 51/0512

(57) ABSTRACT

The present invention discloses an OLED display panel and an OLED display apparatus. The OLED display panel includes a display region and a GOA region, the GOA region is provided with at least one first thin film transistor, the display region is provided with at least one second thin film transistor, the first thin film transistor is an inorganic thin film transistor, the second thin film transistor is an organic thin film transistor. The GOA region of the invention adopts an inorganic thin film transistor, can improve the electron mobility and ensure sufficient gate driving current, and the organic thin film transistor is used in the display region to ensure good bending performance of the OLED display panel and to reduce the cost.

### FIELD OF THE INVENTION

The present application relates to an OLED display technology field, and more particularly to an OLED display panel and OLED display apparatus.

### BACKGROUND OF THE INVENTION

Currently, the backplate of a thin film transistor used in a display apparatus needs to consider various factors such as electrical uniformity, current leakage, effective driving length, region efficiency, hysteresis effect, and the like. For the display apparatus of different display technology, different thin-film transistor structures need to be adapted in order to achieve the desired purpose.

The flexible Organic Light Emitting Diode, OLED display apparatus in the conventional technology requires well bending stability, to adapt Organic Thin Film Transistor. OTFT. Due to the low electron mobility of the OTFT with respect to the inorganic thin film transistor, it cannot provide sufficient gate driving current.

### SUMMARY OF THE INVENTION

The technology to mainly solve in the present application is to provide an OLED display panel and an OLED display apparatus that is capable of increasing electron mobility and ensuring a sufficient gate driving current.

In order to solve the above-mentioned technology problem, a technical approach adopts in the present application is to provide an OLED display panel, wherein the OLED display panel including a display region and a GOA region, at least one first thin film transistor is disposed in the GOA region, at least one second thin film transistor is disposed in the display region, the first thin film transistor is an inorganic thin film transistor, and the second thin film transistor is an organic thin film transistor;

the first thin film transistor including:

a flexible substrate;

a barrier layer disposed on the flexible substrate;

a first polysilicon layer disposed on the barrier layer;

a first source/drain electrode disposed on the barrier layer, and the first source/drain layer is disposed on both sides of the first polysilicon layer;

a first insulating layer disposed on the first polysilicon layer and the first source/drain layer;

a first gate layer disposed on the first insulating layer and disposed above the first polysilicon layer;

the second thin film transistor including:

the flexible substrate and the barrier layer;

a second polysilicon layer disposed on the barrier layer;

the first insulating layer is disposed on the second polysilicon layer;

a second gate layer disposed on the first insulating layer and disposed above the second polysilicon layer;

an ILD layer disposed on the second gate layer and the first insulating layer;

an IOBP layer disposed on the ILD layer;

a second source/drain layer disposed on the IOBP layer;

wherein the first gate layer and the second gate layer are provided in the same layer, the first insulating layer is a gate insulating layer.

Wherein the first gate layer and the second gate layer are provided in the same layer, the first insulating layer is a gate insulating layer.

In order to solve the above-mentioned technology problem, the other technical approach adopts in the present application is to provide an OLED display panel, wherein the OLED display panel including a display region and a GOA region, at least one first thin film transistor is disposed in the GOA region, at least one second thin film transistor is disposed in the display region, the first thin film transistor is an inorganic thin film transistor, and the second thin film transistor is an organic thin film transistor.

Wherein the first thin film transistor including:

a flexible substrate;

a barrier layer disposed on the flexible substrate;

a first polysilicon layer disposed on the barrier layer;

a first source/drain electrode disposed on the barrier layer, and the first source/drain layer is disposed on both sides of the first polysilicon layer;

a first insulating layer disposed on the first polysilicon layer and the first source/drain layer;

a first gate layer disposed on the first insulating layer and disposed above the first polysilicon layer;

Wherein, the second thin film transistor including:

the flexible substrate and the barrier layer;

a second polysilicon layer disposed on the barrier layer;

the first insulating layer is disposed on the second polysilicon layer;

a second gate layer disposed on the first insulating layer and disposed above the second polysilicon layer;

an ILD layer disposed on the second gate layer and the first insulating layer;

an IOBP layer disposed on the ILD layer;

a second source/drain layer disposed on the IOBP layer;

wherein the first gate layer and the second gate layer are provided in the same layer;

wherein the first insulating layer is a gate insulating layer.

Wherein the first thin film transistor including:

a flexible substrate;

a barrier layer disposed on the flexible substrate;

an IGZO layer disposed on the barrier layer;

an first insulating layer disposed on the IGZO layer;

a first gate layer disposed on the first insulating layer and disposed above the IGZO layer;

an ILD layer disposed on the first gate layer and the first insulating layer;

an IOBP layer disposed on the ILD layer;

a first through hole and a second through hole both passing through the IOBP layer, the ILD layer, and the first insulating layer, and are disposed on both sides of the first gate layer;

a first source layer disposed on the IOBP layer and is connected to IGZO layer via the first through hole;

a first drain layer disposed on IOBP layer and is connected to IGZO layer via the second through hole.

Wherein the second thin film transistor including:

the flexible substrate, the barrier layer, and the first insulating layer;

a second gate layer disposed on the first insulating layer:

an ILD layer disposed on the second gate layer and the first insulating layer;

an IOBP layer disposed on the ILD layer; and

a second source/drain layer disposed on the IOBP layer.

wherein the first gate layer and the second gate layer are disposed in the same layer.

wherein the ILD layer and the IOBP layer are gate insulating layer.

In order to solve the above-mentioned technology problem, the other technical approach adopts in the present application is to provide an OLED display apparatus including an OLED display panel, the OLED display panel including a display region and a GOA region, at least one first thin film transistor is disposed in the GOA region, at least one second thin film transistor is disposed in the display region, the first thin film transistor is an inorganic thin film transistor, and the second thin film transistor is an organic thin film transistor.

wherein the first thin film transistor including:

a flexible substrate;

a barrier layer disposed on the flexible substrate;

a first polysilicon layer disposed on the barrier layer;

a first source/drain electrode disposed on the barrier layer, and the first source/drain layer is disposed on both sides of the first polysilicon layer;

a first insulating layer disposed on the first polysilicon layer and the first source/drain layer; and

a first gate layer disposed on the first insulating layer and disposed above the first polysilicon layer.

wherein the second thin film transistor including:

the flexible substrate and the barrier layer;

a second polysilicon layer disposed on the barrier layer;

the first insulating layer is disposed on the second polysilicon layer;

a second gate layer disposed on the first insulating layer and disposed above the second polysilicon layer;

an ILD layer disposed on the second gate layer and the first insulating layer;

an IOBP layer disposed on the ILD layer; and

a second source/drain layer disposed on the IOBP layer.

wherein the first gate layer and the second gate layer are provided in the same layer.

wherein the first insulating layer is a gate insulating layer.

wherein the first thin film transistor including:

a flexible substrate;

a barrier layer disposed on the flexible substrate;

an IGZO layer disposed on the barrier layer;

an first insulating layer disposed on the IGZO layer;

a first gate layer disposed on the first insulating layer and disposed above the IGZO layer;

an ILD layer disposed on the first gate layer and the first insulating layer;

an IOBP layer disposed on the ILD layer;

a first through hole and a second through hole both passing through the IOBP layer, the ILD layer, and the first insulating layer, and are disposed on both sides of the first gate layer;

a first source layer disposed on the IOBP layer and is connected to IGZO layer via the first through hole;

a first drain layer disposed on IOBP layer and is connected to IGZO layer via the second through hole.

wherein the second thin film transistor including:

the flexible substrate, the barrier layer, and the first insulating layer;

a second gate layer disposed on the first insulating layer;

an ILD layer disposed on the second gate layer and the first insulating layer;

an IOBP layer disposed on the ILD layer; and

a second source/drain layer disposed on the IOBP layer.

wherein the first gate layer and the second gate layer are disposed in the same layer.

wherein the ILD layer and the IOBP layer are gate insulating layer.

The advantages of the present invention is, comparing to the conventional technology, the OLED display panel according to the present invention includes a display region and a GOA region, at least one first thin film transistor is provided in the GOA region, at least one second thin film transistor is provided in the display region, the first thin film transistor is an inorganic thin film transistor, and the second thin film transistor is an organic thin film transistor; in the same OLED display panel, the GOA region adopts the inorganic thin film transistor, which can increase the electron mobility and ensure sufficient gate driving current; the display region adopts organic thin film transistor to ensure well bending stability of the OLED display panel and reduce costs.

### BRIEF DESCRIPTION OF THE DRAWINGS

In order to more clearly illustrate the embodiments of the present application or prior art, the following figures will be described in the embodiments are briefly introduced.

It is obvious that the drawings are merely some embodiments of the present application, those of ordinary skill in this field can obtain other figures according to these figures without paying the premise.

FIG. 1 is a schematic structural view of an OLED display panel according to first embodiment of the present application;

FIG. 2 is a cross-sectional view of a first thin-film transistor and a second thin-film transistor illustrated in FIG. 1;

FIG. 3 is a cross-sectional view of a first thin-film transistor and a second thin-film transistor of an OLED display panel according to second embodiment of the present application; and

FIG. 4 is a schematic structural view of an OLED display apparatus according to first embodiment of the present application.

### DETAILED DESCRIPTION OF PREFERRED EMBODIMENTS

Embodiments of the present application are described in detail with the technical matters, structural features, achieved objects, and effects with reference to the accompanying drawings as follows. It is clear that the described embodiments are part of embodiments of the present application, but not all embodiments. Based on the embodiments of the present application, all other embodiments to those of ordinary skill in the premise of no creative efforts acquired should be considered within the scope of protection of the present application.

Specifically, the terminologies in the embodiments of the present application are merely for describing the purpose of the certain embodiment, but not to limit the invention. Embodiments and the claims be implemented in the present application requires the use of the singular form of the book “an”, “the” and “the” are intend to include most forms unless the context clearly dictates otherwise. It should also be understood that the terminology used herein that “and/or” means and includes any or all possible combinations of one or more of the associated listed items.

It is to be noted here that in order to avoid obscuring the present invention with unnecessary detail, only the structure and/or processing steps closely related to the approach according to the invention are shown in the accompanying drawings, other details of the present invention not closed to the present application is omitted.

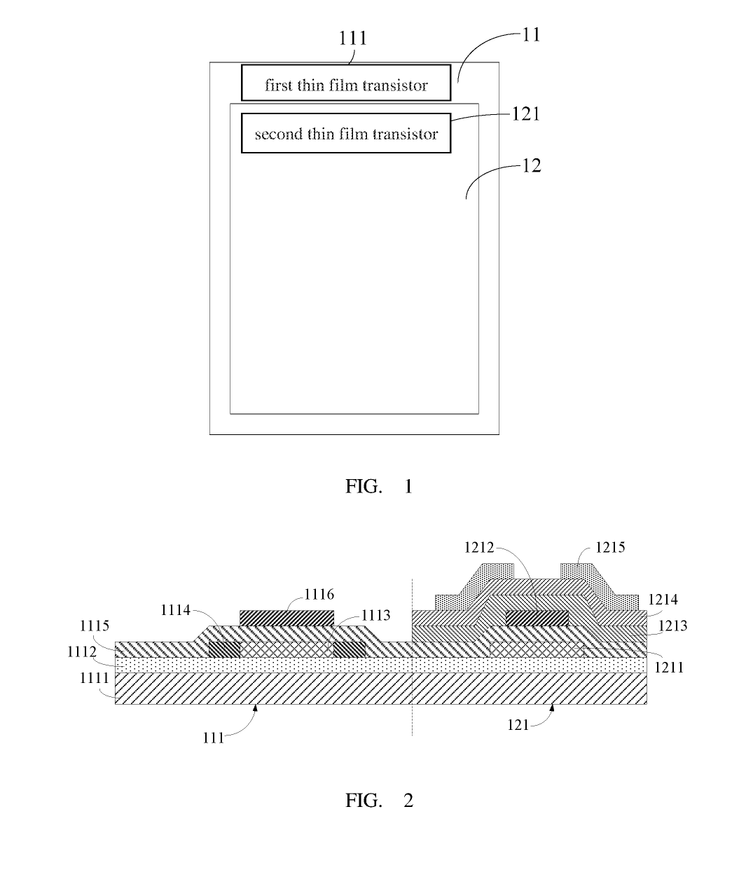

Referring to FIGS. 1-2, FIG. 1 is a schematic structural view of an OLED display panel according to a first embodiment of the present invention; and FIG. 2 is a cross-sectional view of a first thin film transistor and a second thin film transistor illustrated in FIG. 1. Referring to FIG. 1, the OLED display panel 10 disclosed in this embodiment includes a display region 12 and a GOA (Gate on Array, gate driving circuit substrate) region 11, the display region 12 is for displaying image, the GOA region 11 is for generating driving signal, the driving signal is for driving the display region 12 to display image. Wherein at least one first thin film transistor 111 is provided in the GOA region 11, at least one second thin film transistor 121 is provided in the display region 12, the first thin film transistor 111 is an inorganic thin film transistor, and the second thin film transistor 121 is an organic thin film transistor.

As illustrated in FIG. 2, the first thin film transistor 111 is an LTPS (low temperature poly-silicon) transistor, and the second thin film transistor 121 is an OTFT. The first thin film transistor 111 includes a flexible substrate 1111, a barrier layer 1112, a first polysilicon layer 1113, a first source/drain layer 1114, a first insulating layer 1115, and a first gate layer 1116 wherein the barrier layer 1112 is disposed on the flexible substrate 1111, the barrier layer 1112 can reduce the roughness of the flexible substrate 1111 and have the function to block the water and oxygen; the first polysilicon layer (ploy-Si) 1113 is disposed on the barrier layer 1112; the first source/drain electrode 1114 is disposed on the barrier layer 1112, and the first source/drain layer 1114 is disposed on both sides of the first polysilicon layer 1113 to form a source and a drain of the first thin film transistor 111; the first insulating layer 1115 is disposed on the first polysilicon layer 1113 and the first source/drain layer 1114; the first gate layer 1116 is disposed on the first insulating layer 1115 and is disposed above the first polysilicon layer 1113 to form a gate of the first thin film transistor 111. The first thin film transistor 111 employs a top gate structure to ensure the flatness and uniformity of the first polysilicon layer 1113. In addition, the first gate layer 1116 and the first polysilicon layer 1113 constitute a capacitance.

The second thin film transistor 121 includes a flexible substrate 1111, a barrier layer 1112, a second polysilicon layer 1211, a first insulating layer 1115, a second gate layer 1212, an ILD (interlayer insulating layer) layer 1213, an IOBP (Inorganic Barrier Passivation Layer, an inorganic barrier passivation layer 1214, and a second source/drain layer 1215. Wherein, the flexible substrate 1111 and the barrier layer 1112 are the same as the flexible substrate 1111 and the barrier layer 1112 of the first thin film transistor 111. A second polysilicon layer 1211 is disposed on the barrier layer 1112, the first insulating layer 1115 is disposed on the second polysilicon layer 1211; the second gate layer 1212 is disposed on the first insulating layer 1115 and disposed above the second polysilicon layer 1211 to form a gate of the second thin film transistor 121. The ILD layer 1213 is disposed above the second gate layer 1212 and the first insulating layer 1115; the IOBP layer 1214 is disposed on the ILD layer 1213; the second source/drain layer 1215 is disposed on the IOBP layer 1214 to form the source and drain of the second thin film transistor 121, and the second thin film transistor 121 employees a bottom gate structure.

Wherein the first gate layer 1116 and the second gate layer 1212 are provided in the same layer. In addition, the first insulating layer 1115 is a gate insulating layer.

In this embodiment, after completing the first gate layer 1116 and the second gate layer 1212, the array of the first thin film transistor 111 of the GOA region 11 is completed, and then the array of the second thin film transistors 121 of the display region 12 is completed.

The OLED display panel 10 of the present embodiment includes the display region 12 and the GOA region 11, at least one first thin film transistor 111 is provided in the GOA region 11, at least one second thin film transistor 121 is provided in the display region 12, the first thin film transistor 111 is an inorganic thin film transistor, and the second thin film transistor 121 is an organic thin film transistor; In one OLED display panel 10, the inorganic thin film transistor is adopted in the GOA region 11 to increase the electron mobility, and ensure a sufficient gate driving current, the organic thin film transistor is adopted in the display region 12 to ensure that the OLED display panel 10 has good bending properties. In addition, the GOA region 11 and the display region 12 adopt different thin-film transistor structures, which are manufactured at different temperatures, preferably to form at high temperature process, and partial processes of the organic thin-film transistor and the inorganic thin-film transistor can be simultaneously performed, for example, the first gate layer 1116 and the second gate layer 1212 to reduce the cost.

The present invention also provides an OLED display panel of the second embodiment. The difference of the OLED display panel disclosed in this embodiment from the OLED display panel 10 disclosed in the first embodiment is: as illustrated in FIG. 3, the first thin film transistor 211 is an IGZO (indium gallium zinc oxide) transistor, and the second thin film transistor 221 is an OTFT.

The first thin film transistor 211 includes a flexible substrate 2111, a barrier layer 2112, an IGZO layer 2113, a first insulating layer 2114, a first gate layer 2115, an ILD layer 2116, an IOBP layer 2117, a first through hole 2118, a second through hole 2119, a first source layer 2200, and a first drain layer 2201. Wherein the barrier layer 2112 is disposed on the flexible substrate 2111; the IGZO layer 2113 is disposed on the barrier layer 2112; the first insulating layer 2114 is disposed on the IGZO layer 2113 and the barrier layer 2112; the first gate layer 2115 is disposed on the first insulating layer 2114 and disposed above the IGZO layer 2113, the ILD layer 2116 is disposed on the first gate layer 2115 and the first insulating layer 2114, an IOBP layer 2117 is disposed on the ILD layer 2116, the first through hole 2118 and the second through hole 2119 both passing through the IOBP layer 2117, the ILD layer 2116, and the first insulating layer 2114, and are disposed on both sides of the first gate layer 2115. The first source layer 2200 is disposed on the IOBP layer 2117 and is connected to IGZO layer 2113 via the first through hole 2118, the first drain layer 2201 is disposed on IOBP layer 2117 and is connected to IGZO layer 2113 via the second through hole 2119. Since the ILD layer 2116 and the IOBP layer 2117 are gate insulating layers and have a larger thickness, therefore the first thin film transistor 211 is a top gate structure.

The second thin film transistor 221 includes the flexible substrate 2111, the barrier layer 2112, the first insulating layer 2114, the second gate layer 2211, the ILD layer 2116, the IOBP layer 2117, and a second source/drain layer 2212. Wherein the flexible substrate 2111 and the barrier layer 2112 are the same as the flexible substrate 2111 and the barrier layer 2112 of the first thin film transistor 211, the first insulating layer 2114 is disposed on the barrier layer 2112, the second gate layer 2211 is disposed on the first insulating layer 2114; the ILD layer 2116 is disposed on the second gate layer 2211 and the first insulating layer 2114; the IOBP layer 2117 is disposed on the ILD layer 2116; the second source/drain layer 2212 is disposed on the IOBP layer 2117.

Wherein the first gate layer 2115 and the second gate layer 2211 are disposed in the same layer.

In the present embodiment, after the second source/drain layer 2212 is completed, the array of the first thin film transistor 211 of the GOA region 21 is completed first, and then the array of the second thin film transistor 221 of the display region 22 is completed.

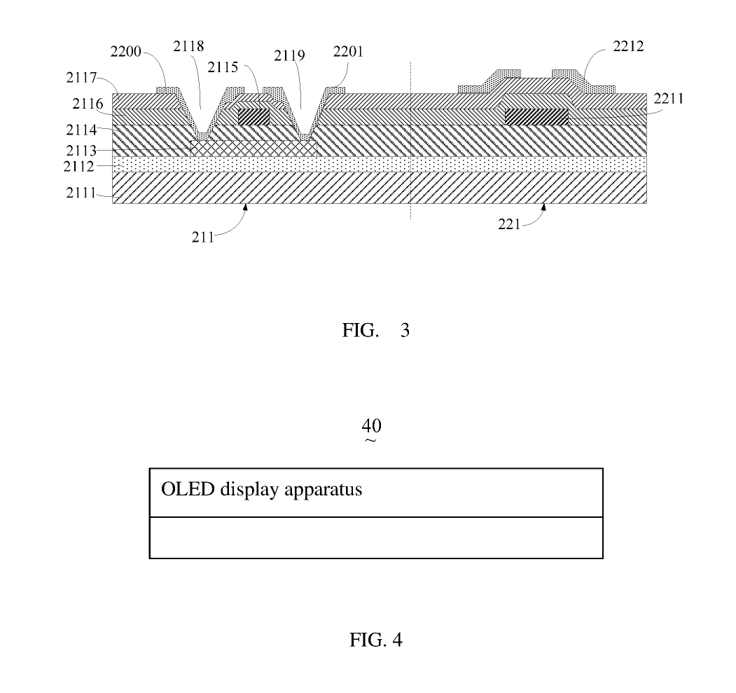

As illustrated in FIG. 4, FIG. 4 is a schematic structural view of an OLED display apparatus according to first embodiment of the present application. As illustrated in FIG. 4, the OLED display apparatus 40 includes the OLED display panel described in the above embodiment, and is not described here. The OLED display apparatus 40 is a flexible OLED display apparatus.

As described above, the OLED display panel of the present invention includes a display region and a GOA region, at least one first thin film transistor is provided in the GOA region, at least one second thin film transistor is provided in the display region, the first thin film transistor is an inorganic thin film transistor, and the second thin film transistor is an organic thin film transistor; in the same OLED display panel, the GOA region adopts the inorganic thin film transistor, which can increase the electron mobility and ensure sufficient gate driving current; the display region adopts organic thin film transistor to ensure well bending stability of the OLED display panel and reduce costs.

Above are embodiments of the present application, which does not limit the scope of the present application. Any modifications, equivalent replacements or improvements within the spirit and principles of the embodiment described above should be covered by the protected scope of the invention.

What is claimed is:

1. An OLED display panel, wherein the OLED display panel comprising a display region and a GOA region, at least one first thin film transistor is disposed in the GOA region, at least one second thin film transistor is disposed in the display region, the first thin film transistor is an inorganic thin film transistor, and the second thin film transistor is an organic thin film transistor;
the first thin film transistor comprising:
a flexible substrate:
a barrier layer disposed on the flexible substrate;
a first polysilicon layer disposed on the barrier layer;
a first source/drain electrode disposed on the barrier layer, and the first source/drain layer is disposed on both sides of the first polysilicon layer;
a first insulating layer disposed on the first polysilicon layer and the first source/drain layer;
a first gate layer disposed on the first insulating layer and disposed above the first polysilicon layer;
the second thin film transistor comprising:
the flexible substrate and the barrier layer;
a second polysilicon layer disposed on the barrier layer;
the first insulating layer is disposed on the second polysilicon layer;
a second gate layer disposed on the first insulating layer and disposed above the second polysilicon layer;
an ILD layer disposed on the second gate layer and the first insulating layer;
an IOBP layer disposed on the ILD layer;
a second source/drain layer disposed on the IOBP layer; and
wherein the first gate layer and the second gate layer are provided in the same layer, the first insulating layer is a gate insulating layer.

2. An OLED display panel, wherein the OLED display panel comprising a display region and a GOA region, at least one first thin film transistor is disposed in the GOA region, at least one second thin film transistor is disposed in the display region, the first thin film transistor is an inorganic thin film transistor, and the second thin film transistor is an organic thin film transistor.

3. The OLED display panel according to claim 2, wherein the first thin film transistor comprising:
a flexible substrate;
a barrier layer disposed on the flexible substrate;
a first polysilicon layer disposed on the barrier layer;
a first source/drain electrode disposed on the barrier layer, and the first source/drain layer is disposed on both sides of the first polysilicon layer;
a first insulating layer disposed on the first polysilicon layer and the first source/drain layer; and
a first gate layer disposed on the first insulating layer and disposed above the first polysilicon layer.

4. The OLED display panel according to claim 3, wherein the second thin film transistor comprising:
the flexible substrate and the barrier layer;
a second polysilicon layer disposed on the barrier layer;
the first insulating layer is disposed on the second polysilicon layer;
a second gate layer disposed on the first insulating layer and disposed above the second polysilicon layer;
an ILD layer disposed on the second gate layer and the first insulating layer;
an IOBP layer disposed on the ILD layer; and
a second source/drain layer disposed on the IOBP layer.

5. The OLED display panel according to claim 4, wherein the first gate layer and the second gate layer are provided in the same layer.

6. The OLED display panel according to claim 4, the first insulating layer is a gate insulating layer.

7. The OLED display panel according to claim 2, wherein the first thin film transistor comprising:
a flexible substrate;
a barrier layer disposed on the flexible substrate;
an IGZO layer disposed on the barrier layer;
an first insulating layer disposed on the IGZO layer;
a first gate layer disposed on the first insulating layer and disposed above the IGZO layer;
an ILD layer disposed on the first gate layer and the first insulating layer;
an IOBP layer disposed on the ILD layer;
a first through hole and a second through hole both passing through the IOBP layer, the ILD layer, and the first insulating layer, and are disposed on both sides of the first gate layer;
a first source layer disposed on the IOBP layer and is connected to IGZO layer via the first through hole; and
a first drain layer disposed on IOBP layer and is connected to IGZO layer via the second through hole.

8. The OLED display panel according to claim 7, wherein the second thin film transistor comprising:
the flexible substrate, the barrier layer, and the first insulating layer;
a second gate layer disposed on the first insulating layer;
an ILD layer disposed on the second gate layer and the first insulating layer;
an IOBP layer disposed on the ILD layer; and
a second source/drain layer disposed on the IOBP layer.

9. The OLED display panel according to claim 8, wherein the first gate layer and the second gate layer are disposed in the same layer.

10. The OLED display panel according to claim 8, wherein the ILD layer and the IOBP layer are gate insulating layer.

11. An OLED display apparatus, wherein the OLED display apparatus comprising an OLED display panel, the OLED display panel comprising a display region and a GOA region, at least one first thin film transistor is disposed in the GOA region, at least one second thin film transistor is disposed in the display region, the first thin film transistor is an inorganic thin film transistor, and the second thin film transistor is an organic thin film transistor.

12. The OLED display apparatus according to claim 11, wherein the first thin film transistor comprising:
a flexible substrate;
a barrier layer disposed on the flexible substrate;
a first polysilicon layer disposed on the barrier layer;
a first source/drain electrode disposed on the barrier layer, and the first source/drain layer is disposed on both sides of the first polysilicon layer;
a first insulating layer disposed on the first polysilicon layer and the first source/drain layer; and
a first gate layer disposed on the first insulating layer and disposed above the first polysilicon layer.

13. The OLED display apparatus according to claim 12, wherein the second thin film transistor comprising:
the flexible substrate and the barrier layer;
a second polysilicon layer disposed on the barrier layer;
the first insulating layer is disposed on the second polysilicon layer;
a second gate layer disposed on the first insulating layer and disposed above the second polysilicon layer;
an ILD layer disposed on the second gate layer and the first insulating layer;
an IOBP layer disposed on the ILD layer; and
a second source/drain layer disposed on the IOBP layer.

14. The OLED display apparatus according to claim 13, wherein the first gate layer and the second gate layer are provided in the same layer.

15. The OLED display apparatus according to claim 13, wherein the first insulating layer is a gate insulating layer.

16. The OLED display apparatus according to claim 11, wherein the first thin film transistor comprising:
a flexible substrate;
a barrier layer disposed on the flexible substrate;
an IGZO layer disposed on the barrier layer;
an first insulating layer disposed on the IGZO layer;
a first gate layer disposed on the first insulating layer and disposed above the IGZO layer;
an ILD layer disposed on the first gate layer and the first insulating layer;
an IOBP layer disposed on the ILD layer;
a first through hole and a second through hole both passing through the IOBP layer, the ILD layer, and the first insulating layer, and are disposed on both sides of the first gate layer;
a first source layer disposed on the IOBP layer and is connected to IGZO layer via the first through hole; and
a first drain layer disposed on IOBP layer and is connected to IGZO layer via the second through hole.

17. The OLED display apparatus according to claim 16, wherein the second thin film transistor comprising:
the flexible substrate, the barrier layer, and the first insulating layer;
a second gate layer disposed on the first insulating layer;
an ILD layer disposed on the second gate layer and the first insulating layer;
an IOBP layer disposed on the ILD layer; and
a second source/drain layer disposed on the IOBP layer.

18. The OLED display apparatus according to claim 17, wherein the first gate layer and the second gate layer are disposed in the same layer.

19. The OLED display apparatus according to claim 17, wherein the ILD layer and the IOBP layer are gate insulating layer.
